(19) United States
(12) Patent Application Publication
(10) Pub. No.: US 2016/0086835 A1
(43) Pub. Date: Mar. 24, 2016

(54) COVER OPENING/CLOSING APPARATUS AND COVER OPENING/CLOSING METHOD

(71) Applicant: Tokyo Electron Limited, Tokyo (JP)

(72) Inventors: Keisuke Kondoh, Yamanashi (JP); Makoto Tashiro, Yamanashi (JP)

(21) Appl. No.: 14/840,616

(22) Filed: Aug. 31, 2015

(30) Foreign Application Priority Data
Sep. 18, 2014 (JP) 2014-190247

(51) Int. Cl. H01L 21/677; H01L 21/673

(52) U.S. Cl. CPC H01L 21/67772; H01L 21/67376

(57) ABSTRACT

Disclosed is a cover opening/closing apparatus including a plurality of placement tables provided in a vertical direction. Each placement table is configured to place thereon a substrate accommodation container including a takeout port in one side surface and a cover that covers the takeout port. The apparatus includes a cover opening/closing mechanism provided to face the cover of the substrate accommodation container placed on each of the placement tables. At least the cover opening/closing mechanism at a placement table side of an upper stage includes: a latch key driven at a time of mounting/removing the cover; a suction port configured to suck gas within a space between the cover opening/closing mechanism and the cover; a cover holding unit configured to suck and hold the cover; and a packing provided at a more outer periphery side than the latch key and the suction port.

### CROSS-REFERENCE TO RELATED APPLICATIONS

This application is based on and claims priority from Japanese Patent Application No. 2014-190247, filed on Sep. 18, 2014, with the Japan Patent Office, the disclosure of which is incorporated herein in its entirety by reference.

### TECHNICAL FIELD

The present disclosure relates to a cover opening/closing apparatus and a cover opening/closing method.

### BACKGROUND

Conventionally, when a semiconductor wafer (hereinafter, also referred to as a “wafer”) as an example of a substrate is conveyed in a semiconductor manufacturing process, the wafer is conveyed in a state where it is accommodated in a sealed substrate accommodation container in order to prevent foreign matter, such as, for example, particles, from adhering to the surface of the wafer. As the substrate accommodation container, for example, a front-opening unified pod (FOUP) specified in the SEMI standard is used. The FOUP refers to a container in which a plurality of wafers can be placed. The FOUP includes a case-type body having a takeout port in a side thereof, and a cover that covers the takeout port.

The FOUP is placed on a placement table of a cover opening/closing apparatus attached to a substrate processing apparatus that performs a predetermined processing on the wafers. In addition, the cover of the FOUP is removed by a cover opening/closing mechanism of the cover opening/closing apparatus, and the wafers are conveyed to the substrate processing apparatus. In addition, the wafers processed by the substrate processing apparatus are carried out from the substrate processing apparatus and accommodated in the FOUP.

What is requested in wafer conveyance by using the FOUP is to improve productivity.

A configuration, in which a plurality of cover opening/closing apparatuses, each including one placement table, are mounted to be parallel with each other in front of a wafer conveyance region of a substrate processing apparatus, is disclosed (see, e.g., Japanese Patent Laid-Open Publication No. 2010-251655).

### SUMMARY

In an aspect of the present disclosure, a cover opening/closing apparatus includes: a plurality of placement tables provided in a vertical direction, each placement table being configured to place thereon a substrate accommodation container that includes a takeout port in one side surface and a cover configured to cover the takeout port; and a cover opening/closing mechanism provided to face the cover of the substrate accommodation container placed on each of the plurality of placement tables. At least the cover opening/closing mechanism at a placement table side of an upper stage includes, on a surface facing the cover: a latch key configured to be driven at a time of mounting/removing the cover; a suction port configured to suck gas within a space between the cover opening/closing mechanism and the cover; a cover holding unit configured to suck and hold the cover; and a packing provided at a more outer periphery side than the latch key and the suction port.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical sectional view illustrating a vertical heat treatment apparatus according to one exemplary embodiment of the present disclosure.

FIG. 2 is a plan view illustrating the vertical heat treatment apparatus according to one exemplary embodiment of the present disclosure.

FIG. 3 is a perspective view illustrating a cover opening/closing apparatus according to one exemplary embodiment of the present disclosure.

FIG. 4 is a perspective view exemplifying a carrier placed on a placement table of the cover opening/closing apparatus according to one exemplary embodiment of the present disclosure.

FIG. 5 is a front sectional view illustrating a cover of the carrier in FIG. 4.

FIG. 6 is an explanatory view illustrating a cover opening/closing method according to one exemplary embodiment of the present disclosure.

FIG. 7 is an explanatory view illustrating the cover opening/closing method according to one exemplary embodiment of the present disclosure.

FIG. 8 is an explanatory view illustrating the cover opening/closing method according to one exemplary embodiment of the present disclosure.

FIG. 9 is an explanatory view illustrating the cover opening/closing method according to one exemplary embodiment of the present disclosure.

FIG. 10 is an explanatory view illustrating the cover opening/closing method according to one exemplary embodiment of the present disclosure.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

In the configuration as described above, there is a problem in that when the number of covering opening/closing apparatuses mounted on the front surface of the wafer conveyance region of the substrate processing apparatus is increased, the area required for providing the cover opening/closing apparatus (hereinafter, referred to as a “foot print”) increases.

With respect to this problem, the increase of the foot print may be suppressed by mounting a cover opening/closing apparatus that includes a plurality of placement tables in the vertical direction of the substrate processing apparatus, on a front side of the wafer conveyance region of the substrate processing apparatus. In such a case, however, foreign matter generated due to, for example, opening/closing of the cover of the substrate accommodation container placed on a placement table of an upper stage among the plurality of placement tables falls down so that the foreign matter may adhere to a wafer within a substrate accommodation container placed on a placement table at a stage lower than the placement table of the upper stage.

Thus, as one aspect, the present disclosure is to suppress foreign matter from adhering to a substrate within a substrate accommodation container placed on a placement table in a cover opening/closing apparatus including a plurality of placement tables in the vertical direction.

According to an aspect of the present disclosure, there is provided a cover opening/closing apparatus including a plurality of placement tables provided in a vertical direction. Each placement table is configured to place thereon a substrate accommodation container that includes a takeout port in one side surface and a cover configured to cover the takeout port. The cover opening/closing apparatus includes a cover opening/closing mechanism provided to face the cover of the substrate accommodation container placed on each of the plurality of placement tables. At least the cover opening/closing mechanism at a placement table side of an upper stage includes, on a surface facing the cover: a latch key configured to be driven at a time of mounting/removing the cover; a suction port configured to suck gas within a space between the cover opening/closing mechanism and the cover; a cover holding unit configured to suck and hold the cover; and a packing provided at a more outer periphery side than the latch key and the suction port.

In the cover opening/closing apparatus described above, the packing is provided to surround the latch key and the suction port.

In the cover opening/closing apparatus described above, the suction port is connected to an exhaust unit, and the exhaust unit is configured to exhaust the gas within the space between the cover opening/closing mechanism and the cover through the suction port.

In the cover opening closing apparatus described above, the packing forms a closed space between the cover opening/closing mechanism and the cover, and the exhaust unit exhausts the gas within the closed space through the suction port.

According to another aspect, there is provided a cover opening/closing method for opening/closing a cover of a substrate accommodation container including a takeout port in one side surface thereof and the cover configured to cover the takeout port by using a cover opening/closing mechanism. The substrate accommodation container is placed on each of a plurality of placement tables of a cover opening/closing apparatus that includes the plurality of placement tables in a vertical direction, and at least the cover opening/closing mechanism positioned at an placement table side of an upper stage includes, on a surface facing the cover, a latch key configured to be driven at a time of attaching/detaching the cover, a suction port connected to an exhaust unit, a cover holding unit configured to suck and hold the cover, and a packing provided at a more outer periphery side than the latch key and the suction port. The cover opening/closing method includes: exhausting gas within a space between the cover opening/closing mechanism at the placement table side of the upper stage and the cover through the suction port before removing the cover of the substrate accommodation container.

The cover closing/opening method described above further includes: making a pressure within a space between the cover opening/closing mechanism at the placement table side of the upper stage and the cover into an atmospheric pressure by the cover opening/closing mechanism at the placement table side of the upper stage after the cover is attached to the substrate accommodation container with the takeout port being opened.

According to an aspect, attachment of foreign matter to a substrate within a substrate accommodation container placed on a placement table can be suppressed in a cover opening/closing apparatus including a plurality of placement tables in the vertical direction.

Hereinafter, exemplary embodiments of the present disclosure will be described with reference to the accompanying drawings. In addition, in the specification and drawings, components having substantially the same functional configurations will be denoted by the same symbols, and repeated descriptions will be omitted.

(General Configuration of Vertical Heat Treatment Apparatus)

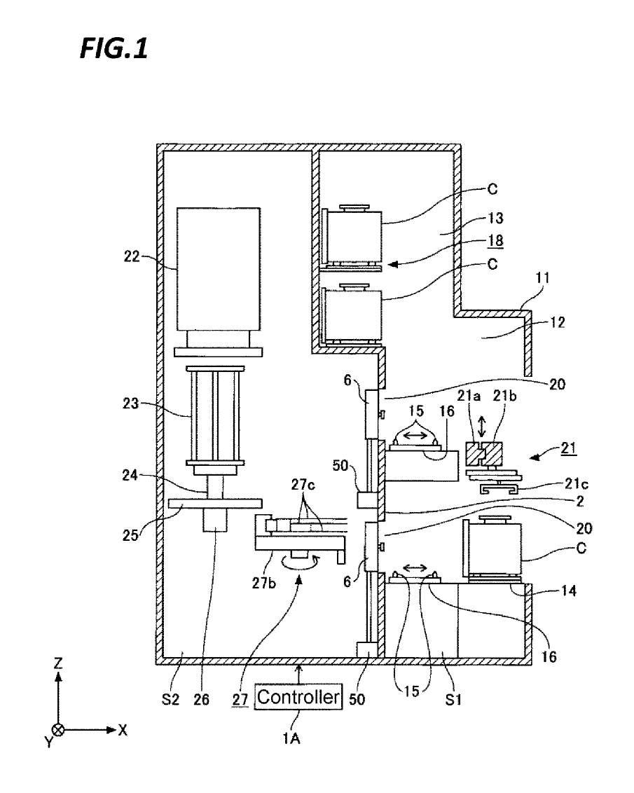

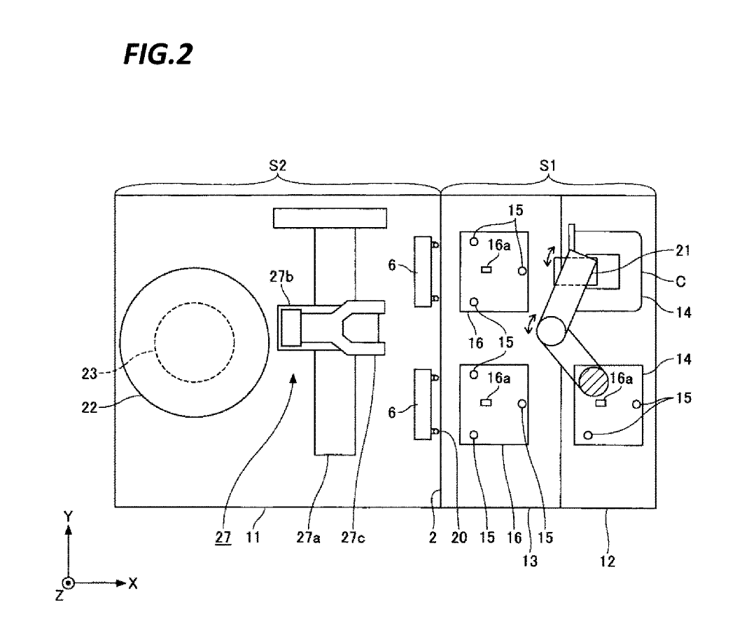

First, a vertical heat treatment apparatus embedded with a cover opening/closing apparatus according to one exemplary embodiment of the present disclosure will be described with reference to FIGS. 1 and 2. While the cover opening/closing apparatus according to the present exemplary embodiment is applicable to a carry-in/out section of various substrate processing apparatus other than the vertical heat treatment apparatus, descriptions will be made on an example of using the cover opening/closing apparatus in the vertical heat treatment apparatus that is one of specific substrate processing apparatuses in the present exemplary embodiment for the convenience of description.

FIG. 1 is a vertical sectional view illustrating a vertical heat treatment apparatus according to one exemplary embodiment of the present disclosure. FIG. 2 is a plan view illustrating the vertical heat treatment apparatus according to one exemplary embodiment of the present disclosure.

As illustrated in FIGS. 1 and 2, the vertical heat treatment apparatus is accommodated in a case 11. The case 11 forms the exterior body of the vertical heat treatment apparatus. Within the case 11, a carrier conveyance region S1 and a wafer conveyance region S2 are formed by being partitioned by a partition wall 2.

A carrier C is an example of a substrate accommodation container. In the following description, it is assumed that an X-direction in FIG. 1 in which the carrier conveyance region S1 and the wafer conveyance region S2 are arranged is the longitudinal direction of the vertical heat treatment apparatus, an Y-direction in FIG. 1 is the transversal direction of the vertical heat treatment apparatus, and a Z-axis in FIG. 1, that is, the height direction, is the vertical direction of the vertical heat treatment apparatus.

The carrier conveyance region S1 is a region that remains under the air atmosphere and allows the carrier C accommodating wafers W as processing target objects to be conveyed (carried in/out) in relation to the heat treatment apparatus. A region between a plurality of processing apparatuses corresponds to the carrier conveyance region S1, and in the present exemplary embodiment, a space within a clean room in the outside of the vertical heat treatment apparatus corresponds to the carrier conveyance region S1.

In addition, the carrier conveyance region S1 includes a first conveyance region 12, and a second conveyance region 13 positioned at the rear side of the first conveyance region 12 (the wafer conveyance region S2 side).

The first conveyance region 12 is a region in which the carrier C is placed by, for example, an automatic conveyance robot moving along a ceiling or a bottom of the clean room. Two first placement tables 14, on each of which one carrier C may be placed, are provided in the transversal direction of the first conveyance region 12. On the placement surface of each first placement table 14, protrusions 15 for positioning the carrier C are provided at, for example, three locations.

In the first conveyance region 12, a carrier conveyance mechanism 21 is provided to convey the carriers C between any of the first placement tables 14 and the second placement tables 16 (to be described later) and a carrier storing section 18 (to be described later). The carrier conveyance mechanism 21 includes a liftable guide unit 21a extending in the transversal direction, a moving unit 21b moving in the transversal direction while being guided by the guide unit 21a, and an articulated arm 21c provided on the moving unit 21b to hold and convey the carriers C in the horizontal direction.

In the second conveyance region 13, a plurality of second placement tables 16, on each of which one carrier C may be placed, are provided to be aligned in the longitudinal direction in relation to the first placement tables 14. In the present exemplary embodiment, as illustrated in FIG. 1, the second placement tables 16, configured to place the carriers C in the vertical direction of the second conveyance region 13, are provided in two stages, and as illustrated in FIG. 2, the second placement tables 16, configured to place the carriers C in the transversal direction of the second conveyance region 13, are provided in two rows. That is, four (two in the vertical direction and two in the transversal direction) second placement tables 16 are provided in the second conveyance region 13.

The second placement tables 16 are not particularly limited so long as they are provided in multiple stages in the vertical direction. For example, the second placement tables 16 may be provided in three stages in the vertical direction and in one row in the transversal direction. In such a case, since the number of cover opening/closing apparatuses arranged in parallel with each other is reduced, the increase of foot print may be suppressed. In addition, since the number of cover opening/closing apparatuses required for providing the same number of second placement tables 16 is reduced, the costs for manufacturing the cover opening/closing apparatuses may be reduced.

The second placement tables 16 are configured to be movable back and forth. On each of the placement surfaces of the second placement tables 16, protrusions 15 for positioning the carrier C are provided at, for example, three locations, similarly to those of the first placement tables 14. In addition, on each of the placement surfaces of the second placement tables 16, a hook 16a is provided to fix the carrier C.

At the positions on the partition wall 2 which correspond to the positions where the second placement tables 16 are provided, conveyance ports 20 of wafers W are provided to communicate the carrier conveyance regions S1 and the wafer conveyance region S2 with each other. In each conveyance port 20, a cover opening/closing mechanism 6 is provided to cover the conveyance port 20 from the wafer conveyance region S2 side. A driving mechanism 50 is connected to the cover opening/closing mechanism 6, and the cover opening/closing mechanism 6 is configured to be movable back and forth and up and down by the driving mechanism 50 so as to open/close the conveyance port 20.

The operation of opening/closing the conveyance port 20 by the cover opening/closing mechanism 6 is not particularly limited. For example, the opening moving directions at the time of switching the cover opening/closing mechanisms 6 provided in two stages in the vertical direction from the closed state to the open state may be set to the same direction, for example, in the downward direction. In addition, for example, the opening moving directions at the time of switching the cover opening/closing mechanisms 6 provided in two stages in the vertical direction from the closed state to the open state may be set to be different from each other. That is, the opening moving direction of the cover opening/closing mechanism 6 of the upper stage may be set to be the upward direction, and the opening moving direction of the lower cover opening/closing mechanism 6 may be set to be the downward direction. The same shall apply to the case where the cover opening/closing mechanisms 6 are switched from the opened state to the closed state.

At the upper side of the second conveyance region 13, a carrier storing section 18 is provided so as to store the carriers C, as illustrated in FIG. 1. The carrier storing section 18 is configured by two or more stages of shelves, and two carries C may be placed from side to side on each of the shelves. While FIG. 1 illustrates two stages of shelves as an example, the present disclosure is not limited thereto.

The wafer conveyance region S2 is a transfer region in which the wafers W within the carriers C are conveyed and carried into a heat treatment furnace 22 to be described later. The wafer conveyance region S2 is in an inert gas atmosphere, for example, a nitrogen (N₂) gas atmosphere in order to prevent an oxide film from being formed on the wafers W carried therein, so that the wafer conveyance region S2 remains at a higher cleanliness and a lower oxygen concentration than the carrier conveyance region S1.

In the wafer conveyance region S2, a vertical heat treatment furnace 22 having a lower end opened as a furnace port is provided. Under the heat treatment furnace 22, a wafer boat 23 configured to hold a plurality of wafers W in a shelf-like state is mounted on a cap 25 via an insulation member 24. The cap 25 is supported on a lift mechanism 26, and the wafer boat 23 is carried into/out of the heat treatment furnace 22 by the lift mechanism 26.

In addition, a wafer conveyance mechanism 27 is provided between the wafer boat 23 and the conveyance ports 20 of the partition wall 2. As illustrated in FIG. 2, the wafer conveyance mechanism 27 includes a guide mechanism 27a extending in the transversal direction. In addition, as illustrated in FIG. 1, the wafer conveyance mechanism includes a moving body 27b configured to turn around a vertical axis and a plurality of arms 27c configured to freely advance/retreat. In addition, the wafer conveyance mechanism 27 conveys wafers W between the wafer boat 23 and the carriers C on the second placement tables 16 through the movement along the guide mechanism 27a, the turning around the vertical axis by the moving body 27b, and the advancement/retreat by the arm 27c.

In addition, the vertical heat treatment apparatus is provided with a controller 1A configured by, for example, a computer, as illustrated in FIG. 1. The controller 1A includes, for example, a program, a memory, and a data processing unit configured as a CPU. Instructions (respective steps) are incorporated in the program to cause control signals to be sent to the respective components of the vertical heat treatment apparatus from the controller 1A so as to advance each process. In response to the control signals, operations such as, for example, conveyance of a carrier C, conveyance of a wafer W, opening/closing of the cover 41, operation of the cover opening/closing mechanism 6, are controlled so that the conveyance and processings of the wafers W are performed.

The program is stored in a computer storage medium, for example, a storage medium such as, for example, a flexible disc, a compact disc, a hard disc, a MO disc (magneto-optical disc), or a memory card, and installed in the controller 1A.

(Configuration of Cover Opening/Closing Apparatus)

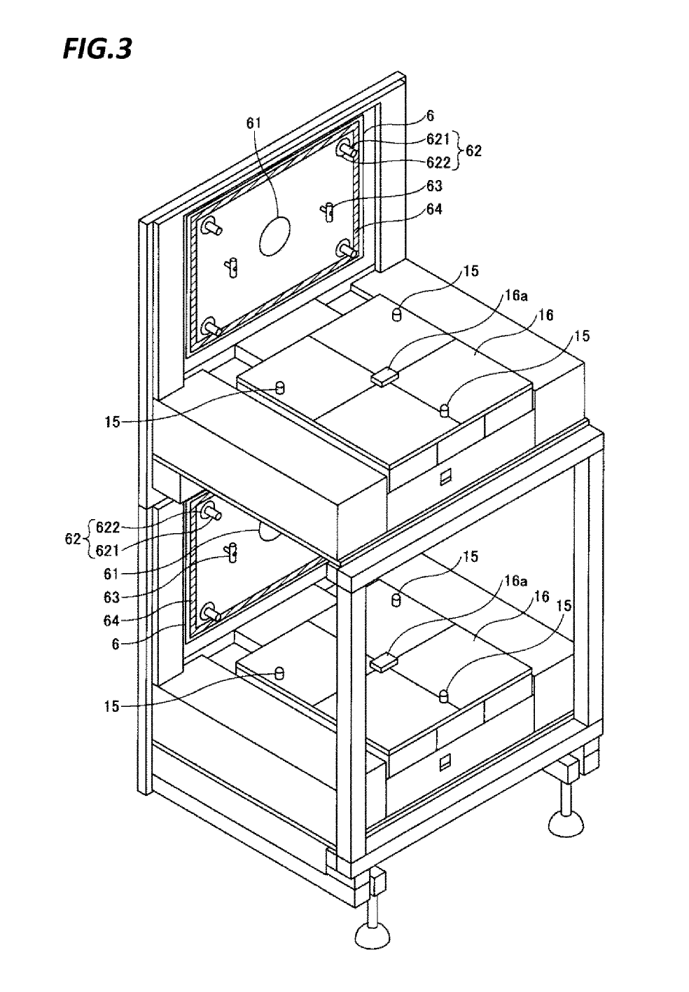

Next, descriptions will be made on details of the configuration of the cover opening/closing apparatus with reference to FIG. 3. The cover opening/closing apparatus according to the present embodiment is a load port that is mounted on various substrate processing apparatuses so as to automatically open/close the cover 41 of a carrier C.

FIG. 3 is a perspective view illustrating a cover opening/closing apparatus according to one exemplary embodiment of the present disclosure.

As illustrated in FIG. 3, the cover opening/closing apparatus includes second placement tables 16 provided in two stages in the vertical direction, and cover opening/closing mechanisms 6 provided in two stages in the vertical direction similarly to the second placement tables 16.

On the placement surface of each second placement table 16, protrusions 15 for positioning a carrier C are provided at, for example, three locations, as described above. In addition, on the placement surface of each second placement table 16, a hook 16a for fixing the carrier C is provided.

Each cover opening/closing mechanisms 6 has a function of removing a cover 41 or a function of mounting the cover 41 from the carrier conveyance region S1.

Each cover opening/closing mechanism 6 includes a suction port 61, a cover holding unit 62, a latch key 63, and a packing 64 on the carrier conveyance region S1 side surface.

The suction port 61 is a hole provided on the carrier conveyance region S1 side surface of the cover opening/closing mechanism 6 and connected to an exhaust means via, for example, an air tube. For example, as illustrated in FIG. 3, the suction port 61 is provided in the central portion of the carrier conveyance region S1 side surface of the cover opening/closing mechanism 6. The exhaust means exhausts the gas within the carrier conveyance region S1 side space of the cover opening/closing mechanism 6 through, for example, the air tube and the suction port 61. In addition, in the present exemplary embodiment, one suction port 61 is provided in the central portion of the carrier conveyance region S1 side surface of the cover opening/closing mechanism 6, but the present disclosure is not limited thereto. A plurality of suction ports 61 may be provided, and the suction port may be provided in another portion of the carrier conveyance region S1 side surface of the cover opening/closing mechanism 6.

The cover holding unit 62 is provided on the carrier conveyance region S1 side surface of the cover opening/closing mechanism 6 to suck and hold the cover 41 of a carrier C. In the present exemplary embodiment, four cover holding units 62 are provided on the carrier conveyance region S1 side surface of the cover opening/closing mechanism 6. However, the number of cover holding units 41 is not particularly limited and may be, for example, two if the cover holding units 41 are capable of sucking and holding the cover 41 of the carrier C.

In addition, each cover holding unit 62 includes a registration pin 621 and a suction pad unit 622. The registration pin 621 refers to a pin for performing positioning of the carrier C by being engaged with a recess 410 of the cover 41 of the carrier C which will be described later. The registration pin 621 is formed in a tubular shape and connected to an exhaust system such as, for example, a vacuum pump. The suction pad unit 622 refers to a suction pad configured to suck and hold the cover 41 of the carrier C. As the material of the suction pad, for example, a natural rubber or a synthetic rubber may be used, but not particularly limited thereto.

The cover holding unit 62 performs exhaust when the registration pin 621 is engaged with the recess 401 of the cover 41 of the carrier C, and sucks the cover 41 by the suction pad unit 622, thereby vacuum-sucking and holding the cover 41.

The latch key 63 refers to a key provided on the carrier conveyance region S1 side surface of the cover opening/closing mechanism 6 so as to be driven when mounting or removing the cover 41. The latch key 63 is engaged in an insertion hole 40 of the cover 41 of the carrier C which will be described later, and, for example, when the latch key 63 is turned 90 degrees from the vertical position to the horizontal position, the locking of the cover 41 of the carrier C is released.

The packing 64 is provided on the carrier conveyance region S1 side surface of the cover opening/closing mechanism 6, and located close to the outer periphery side as compared to the suction port 61 and the latch key 63. As illustrated in FIG. 3, the packing 64 may be disposed on the outer peripheral portion of the carrier conveyance region S1 side surface of the cover opening/closing mechanism 6 so as to enclose the suction ports 61 and the latch keys 63. As the packing 64 is disposed on the outer peripheral portion of the carrier conveyance region S1 side surface of the cover opening/closing mechanism 6 so as to enclose the suction ports 61 and the latch keys 63, the adhesion between the cover opening/closing mechanism 6 and the cover 41 is improved. In addition, since the space between the cover opening/closing mechanism 6 and the cover 41 becomes a closed space or a substantially closed space, the exhaust efficiency at the time of exhausting the gas within the space between the cover opening/closing mechanism 6 and the cover 41 through the suction port 61 by the exhaust means is improved. As a result, for example, foreign matter attached to the surface of the cover 41 facing the cover opening/closing mechanism 6 may be efficiently sucked. For this reason, foreign matter, generated due to, for example, opening/closing of the cover 41 of the carrier C placed on an second placement table 16 of the upper stage, can be suppressed from adhering to the wafers within a substrate accommodate container placed on a lower placement table than the second placement table 16 of the upper stage by dropping downward. As a result, adhering of foreign matter to the wafers W within the carrier C placed on the placement table lower than the second placement table 16 of the upper stage can be suppressed.

In the present exemplary embodiment, descriptions have been made on a cover opening/closing apparatus in which the respective second placement tables 16 provided in two stages in the vertical (height) direction have the same configuration, but the present disclosure is not limited thereto. The cover opening/closing apparatus may be configured such that at least the cover opening/closing mechanism 6 positioned at the second placement table 16 side of the upper stage includes the suction ports 61, the cover holding units 62, the latch keys 63, and the packing 64 on the surface facing the cover 41. With this arrangement, the attachment of foreign matter to the wafers W within the carrier C placed on the second placement table 16 lower than the second placement table 16 of the upper stage can be suppressed.

Herein, the term, “upper stage” indicates all the stages, except for the lowermost stage. For example, the “upper stage” in the cover opening/closing apparatus including two stages of placement tables in the vertical direction indicates one stage at the upper side in the two stages. In addition, the “upper stage” in a cover opening/closing apparatus including three stages of placement tables in the vertical direction indicates two stages at the upper side, except for the lowermost stage among the three stages.

(Configuration of Carrier)

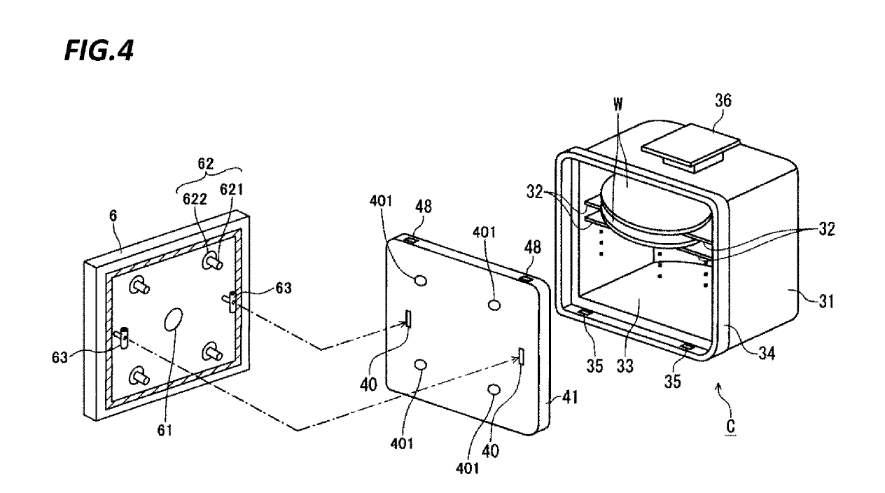

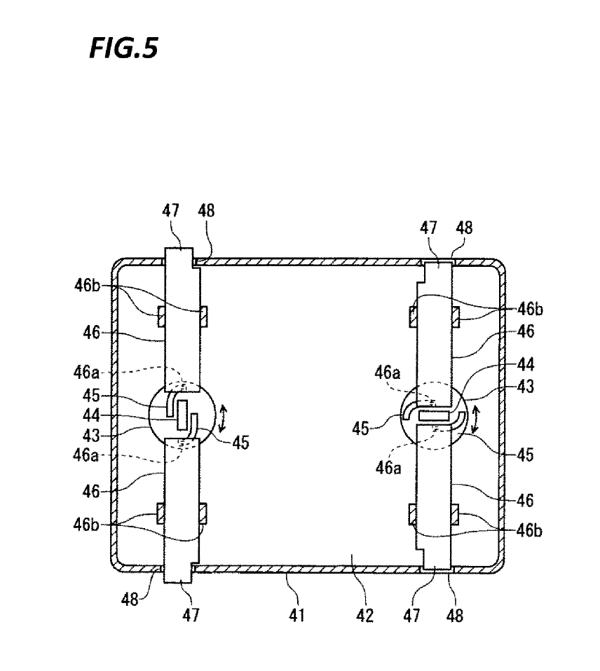

Next, descriptions will be made on a carrier C with reference to FIGS. 4 and 5. FIG. 4 is a perspective view exemplifying a carrier placed on a placement table of a cover opening/closing apparatus according to one exemplary embodiment of the present disclosure. FIG. 5 is a front sectional view of the cover of the carrier in FIG. 4.

As illustrated in FIG. 4, a carrier C includes a carrier body 31 and a cover 41.

The carrier body 31 is a container body having a wafer W takeout port 33 formed in the front surface which is one side surface thereof. On the internal surfaces of the carrier body 31, support units 32 are provided in multiple stages to support rear side peripheral edges of wafers W. In addition, on each of the upper and lower portions of the inner periphery of the opening edge 34 of the takeout port 33, two engagement grooves 35 are formed.

On the top of the carrier body 31, a gripping portion 36 is provided so that the above-described carrier conveyance mechanism 21 may grip the carrier C when conveying the carrier C.

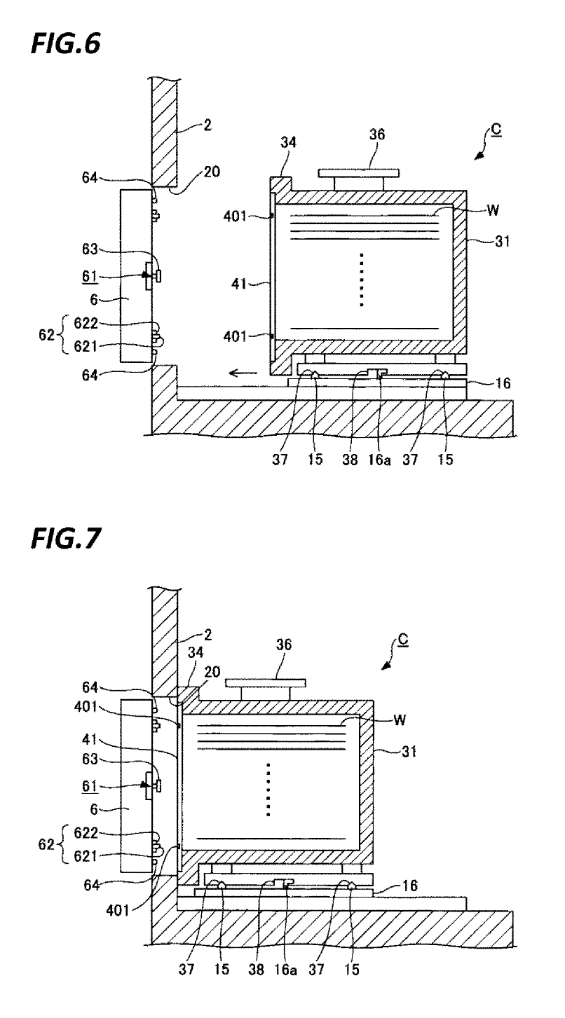

As illustrated in FIG. 6 to be described later, recesses 37 and a groove 38 are provided in the lower portion of the carrier body 31. The recesses 37 are fitted to the protrusions 15 of either the first placement table 14 or the second placement table 16. The recess 38 is engaged with the hook 16a of the second placement table 16. Due to the engagement, the carrier body 31 is fixed to the second placement table 16.

The cover 41 refers to a cover that covers the takeout port 33 of the carrier body 31. As illustrated in FIG. 5, the cover 41 is formed with an inner space 42, and disc-shaped rotary motion units 43, each configured to be turned around a horizontal axis, are provided in the left and right portions of the inner space 42.

Each rotary motion unit 43 includes an engagement hole 44 engaged with the latch key 63 and slits 45. Above and below each rotary motion unit 43, linear motion units 46 are provided. Each linear motion unit 46 is provided with a pin 46a at a base end side thereof in which the pin 46a extends in the thickness direction of the cover 41 and enters into the slits. Each linear motion unit 46 is also provided with a guide 46b. When the rotary motion unit 43 is turned by 90 degrees, the pins 46a are moved within the slits 45 in response to the movement of the slits 45 so that the linear motion units 46 are moved upward and downward. Thereby, the engagement portions 47 that form the tip ends of the linear motion units 46 protrude to/retract from the outside of the cover 41 through the openings 48 provided through the upper and lower portions of the cover 41. When the engagement portions 47 protruding to the outside of the cover 41 are engaged in the engagement grooves 35 of the opening edge 34 of the carrier body 31, the cover 41 is fixed to the carrier body 31.

In FIG. 5, the left engagement portions 47 are illustrated in the state where they protrude to the outside of the cover 41 so as to fix the cover 41, and the right engagement portions 47 are illustrated in the state where they are retracted into the inner space 42 so as to release the fixing of the cover 41. In fact, the left and right engagement portions 47 are mutually aligned to retract into the inner space 42 and protrude to the outside of the cover 41. For example, the carrier C may be provided with such a locking mechanism so as to lock the cover 41 to the carrier body 31.

As illustrated in FIG. 4, on the front surface of the cover 41, the insertion holes 40 of the latch keys 64 are opened to overlap the engagement holes 44 of the rotary motion units 43. The locking of the cover 41 of the carrier C may be released by inserting the latch keys 63 into the insertion holes 40 to reach the engagement holes 44 and rotating the rotary motion units 43.

On the front surface of the cover 41, positioning recesses 401 are formed. Also, when opposite registration pins 621 of the cover holding units 62 are inserted into the recesses 401, respectively, positioning between the cover opening/closing mechanism 6 and the carrier C can be performed. In addition, when the registration pins 621 are engaged with the recesses 401, respectively, vacuum-exhaust is performed so that the cover 41 is sucked by the suction pad unit 622, and thus, the cover 41 is sucked and held by vacuum.

(Operation of Cover Opening/Closing Apparatus)

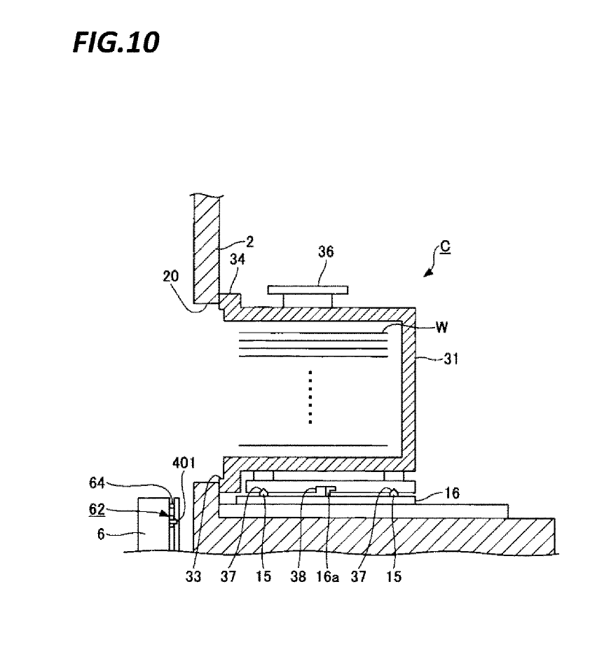

Next, an exemplary operation of the cover opening/closing apparatus (a cover opening/closing method) according to the present exemplary embodiment will be described with reference to FIGS. 1, 2, and 6 to 10. FIGS. 6 to 10 are explanatory views illustrating a cover opening/closing method according to an exemplary embodiment of the present disclosure. In FIGS. 6 and 10, only a second placement table 16 in the upper stage is illustrated among the second placement tables 16 provided in two stages in the vertical direction for the convenience of description.

In FIGS. 1 and 2, first, a carrier C is placed (loaded) on a first placement table 14 by an automatic conveyance robot moving along, for example, the ceiling or bottom of a clean room. Subsequently, the carrier C placed on the first placement table 14 is conveyed to the second placement table 16 from the first placement table 14 by the carrier conveyance mechanism 21. Subsequently, the carrier C placed on the second placement table 16 is fixed to the second placement table 16 by the hook 16a provided on the placement surface of the second placement table 16 (FIG. 6).

Subsequently, as indicate by an arrow in FIG. 6, the second placement table 16 is moved toward the partition wall 2 so that the carrier C fixed to the second placement table 16 is moved toward the partition wall 2. Then, the opening edge 34 of the carrier C comes in contact with an inlet edge around a conveyance port 20 of the partition wall 2 (FIG. 7). At this time, a seal member may be provided between the opening edge 34 of the carrier C and the inlet edge around the conveyance port 20 of the partition wall 2 in order to enhance the airtightness.

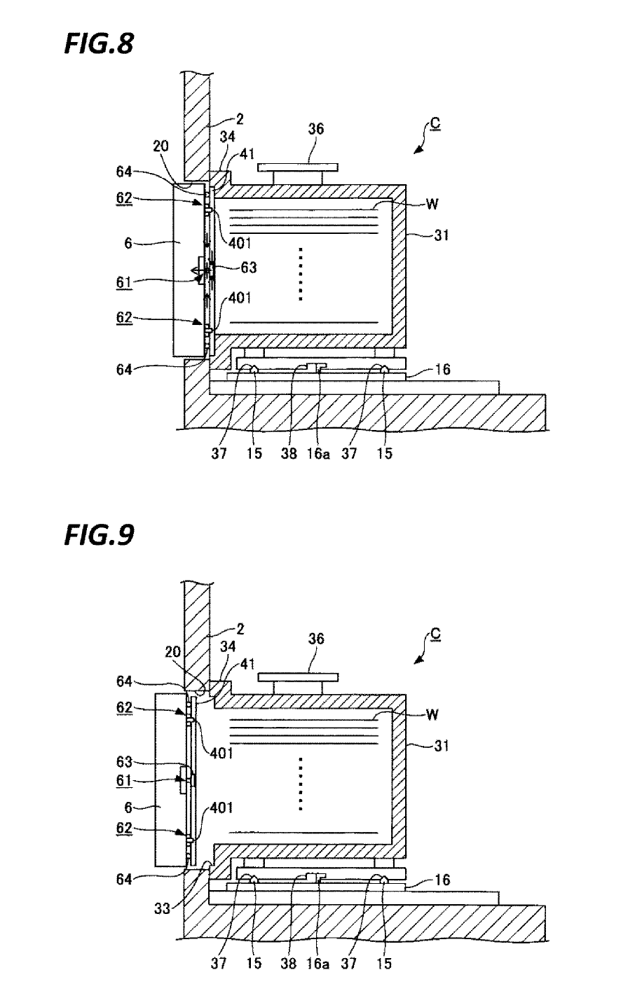

Subsequently, when the cover opening/closing mechanism 6 is moved toward the carrier C to be in contact with the cover 41, the cover holding unit 62 sucks and holds the cover 41. In addition, the latch keys 63 are introduced into the inner space 42 of the cover 41 through the insertion holes 40 on the front surface of the cover 41, and inserted into the engagement holes 44 of the rotary motion units 43 to be engaged with the rotary motion units 43, respectively (FIG. 8). At this time, the cover opening/closing mechanism 6 and the cover 41 are in close contact with each other by the packing 64 of the cover opening/closing mechanism 6.

Subsequently, in the state where the latch keys 63 and the rotary motion units 43 are engaged with each other, exhaust of the gas within the space between the cover opening/closing mechanism 6 and the cover 41 is initiated through the suction port 61. Then, foreign matter such as, for example, particles within the inner space 42 which are attached to the surface of the cover 41 facing the cover opening/closing mechanism 6 and the inner portion of the cover 41, is exhausted through the suction port (see the arrow in FIG. 8). For this reason, for example, when the cover 41 is removed from the carrier body 31 by the cover opening/closing mechanism 6, the foreign matter attached to the cover 41 and the inside of the cover 41 may be suppressed from falling down. In addition, since the cover opening/closing mechanism 6 and the cover 41 are in close contact with each other via the packing, for example, the foreign matter attached to the surface of the cover 41 facing the cover opening/closing mechanism 6 is sucked through the suction port 61 before falling down. As a result, attachment of the foreign matter to the wafers W within the carrier C placed on the second placement table 16 may be suppressed.

Subsequently, in the state where the exhaust of the gas within the space between the cover opening/closing mechanism 6 and the cover 41 through the suction port 61 is continued, the latch keys 63 are rotated by, for example, 90 degrees. Then, the rotary motion units 43 of the cover 41 are rotated which causes the engagement portions 47 at the tip ends of the linear motion units 46 to be retracted into the cover 41 so that the engagement between the engagement portions 47 and the engagement grooves 35 of the carrier body 31 is released. As a result, the coupling of the cover 41 to the carrier body 31 is released and the cover 41 is held on the latch keys 63.

In addition, foreign matter may be generated within the cover 41 due to abrasion between the engagement portions 47 and the cover 41 when the engagement portions 47 at the tip ends of the linear motion units 46 are retracted into the cover 41. In addition, the foreign matter generated within the cover 41 may fall down, for example, when the cover 41 is moved toward the wafer conveyance region S2 by the cover opening/closing mechanism 6. Furthermore, when the carrier C is placed on the second placement table 16 provided below the above-mentioned second placement table 16 and the cover 41 of the carrier C is opened, foreign mater may be attached to the wafers W within the carrier C placed on the second placement table 16 provided below the above-mentioned second placement table 16.

However, according to the cover opening/closing apparatus of the present exemplary embodiment, the cover opening/closing mechanism 6 includes the suction port 61, the cover holding units 62, the latch keys 63, and the packing 64 on the surface facing the cover 41. In addition, the suction port 61 is connected to an exhaust means, and the packing 64 is provided at a more outer peripheral side than the latch keys 63 and the suction port 61 in the surface of the cover opening/closing mechanism 6 which faces the cover 41. For this reason, even if foreign matter is generated inside the cover 41 due to abrasion between the engagement portion 47 and the cover 41, the generated foreign matter is exhausted through the insertion holes 40 of the cover 41 and the suction port 61 of the cover opening/closing mechanism 6. As a result, attachment of foreign matter to the wafers W within the carrier C disposed on the second placement table 16 can be suppressed.

Subsequently, after the locking of the cover 41 and the carrier body 31 is released, the cover 41 retreats toward the wafer conveyance region S2 in the state where it is held by the cover holding unit 62 of the cover opening/closing mechanism 6. As such, the wafer W takeout port 33 of the carrier body 31 is opened (FIG. 9). In addition, during this process, the gas within the space between the cover opening/closing mechanism 6 and the cover 41 is continuously exhausted through the suction port 61.

Subsequently, after having retreated toward the wafer conveyance region S2, the cover opening/closing mechanism 6 moves down and retreats from the conveyance port 20. As such, the inside of the carrier C is opened to the wafer conveyance region S2 (FIG. 10).

Subsequently, as illustrated in FIG. 1, the wafers W within the carrier C are sequentially taken out by the wafer conveyance mechanism 27 and transferred to the wafer boat 23. Then, when the wafers W within the carrier C are emptied out, the cover 41 of the carrier C is closed and fixed to the carrier body 31 by the operations opposite to the above-mentioned operations. In addition, after the cover 41 is fixed to the carrier body 31, the exhaust of the gas within the space between the cover opening/closing mechanism 6 and the cover 41 is stopped. In addition, the pressure within the space between the cover opening/closing mechanism 6 and the cover 41 is made into the atmospheric pressure. The method of making the pressure within the space between the cover opening/closing mechanism 6 and the cover 41 into an atmospheric pressure is not particularly limited, but is, for example, to supply, for example, air or an inert gas into the space between the cover opening/closing mechanism 6 and the cover 41.

Subsequently, the second placement table 16 retreats so that the carrier C is moved away from the partition wall 2, and the carrier C is conveyed to, for example, the carry storing section 18 by the carrier conveyance mechanism 21 and temporarily stored therein.

Meanwhile, the wafer boat 23 loaded with the wafers W is carried into the heat treatment furnace 22, and heat treatments such as, for example, CVD, annealing, and oxidation processes, are performed on the wafers W. In addition, when the wafers W completely subjected to the heat treatments are returned to the carrier C, the cover 41 is opened by the procedures similar to those performed when taking out the wafers W from the carrier C. After having been completely subjected to the heat treatments, the wafers W are transferred from the wafer boat 23 to the carrier C by the wafer conveyance mechanism 27.

Subsequently, the cover 41 of the carrier C is closed and fixed to the carrier body 31 by the operations opposite to the above-described operations. After the cover 41 is fixed to the carrier body 31, the exhaust of the gas within the space between the cover opening/closing mechanism 6 and the cover 41 is stopped. In addition, the pressure within the space between the cover opening/closing mechanism 6 and the cover 41 is made into the atmospheric pressure.

Subsequently, the second placement table 16 retreats so that the carrier C is moved away from the partition wall 2, and the carrier C is conveyed by the carrier conveyance mechanism 21 to the first placement table 14. Subsequently, the carrier C conveyed to the first placement table 14 is removed (unloaded) from the first placement table 14 by an automatic conveyance robot that moves along, for example, the ceiling or bottom of the clean room.

As described above, according to the cover opening/closing apparatus and the cover opening/closing method of the present exemplary embodiments, attachment of foreign matter to substrates within a substrate accommodation container placed on a placement table can be suppressed in a cover opening/closing apparatus including a plurality of placement tables in the vertical direction.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A cover opening/closing apparatus comprising:
a plurality of placement tables provided in a vertical direction, each placement table being configured to place thereon a substrate accommodation container that includes a takeout port in one side surface and a cover configured to cover the takeout port; and
a cover opening/closing mechanism provided to face the cover of the substrate accommodation container placed on each of the plurality of placement tables,
wherein at least the cover opening/closing mechanism at a placement table side of an upper stage includes, on a surface facing the cover:
a latch key configured to be driven at a time of mounting/removing the cover;
a suction port configured to suck gas within a space between the cover opening/closing mechanism and the cover;
a cover holding unit configured to suck and hold the cover; and
a packing provided at a more outer periphery side than the latch key and the suction port.

2. The cover opening/closing apparatus of claim 1, wherein the packing is provided to surround the latch key and the suction port.

3. The cover opening/closing apparatus of claim 1, wherein the suction port is connected to an exhaust unit, and
the exhaust unit is configured to exhaust the gas within the space between the cover opening/closing mechanism and the cover through the suction port.

4. The cover opening closing apparatus of claim 3, wherein the packing forms a closed space between the cover opening/closing mechanism and the cover, and the exhaust unit exhausts the gas within the closed space through the suction port.

5. A cover opening/closing method for opening/closing a cover of a substrate accommodation container including a takeout port in one side surface thereof and the cover configured to cover the takeout port by using a cover opening/closing mechanism, the substrate accommodation container being placed on each of a plurality of placement tables of a cover opening/closing apparatus that includes the plurality of placement tables in a vertical direction, and at least the cover opening/closing mechanism positioned at an placement table side of an upper stage includes, on a surface facing the cover, a latch key configured to be driven at a time of attaching/detaching the cover, a suction port connected to an exhaust unit, a cover holding unit configured to suck and hold the cover, and a packing provided at a more outer periphery side than the latch key and the suction port, the cover opening/closing method comprising:
exhausting gas within a space between the cover opening/closing mechanism at the placement table side of the upper stage and the cover through the suction port before removing the cover of the substrate accommodation container.

6. The method of claim 5, further comprising:
making a pressure within a space between the cover opening/closing mechanism at the placement table side of the upper stage and the cover into an atmospheric pressure by the cover opening/closing mechanism at the placement table side of the upper stage after the cover is attached to the substrate accommodation container with the takeout port being opened.
